(19) United States
(12) Patent Application Publication
(10) Pub. No.: US 2003/0094967 A1
(43) Pub. Date: May 22, 2003

(54) Signal-off detection circuit and optical receiving device using the same

(75) Inventors: Hidemi Noguchi, Tokyo (JP); Tetuo Tateyama, Tokyo (JP); Madoka Kimura, Miyagi (JP)

Correspondence Address: YOUNG & THOMPSON, 745 SOUTH 23RD STREET 2ND FLOOR, ARLINGTON, VA, 22202

(73) Assignee: NEC CORPORATION, Tokyo (JP)

(21) Appl. No.: 10/292,432

(22) Filed: Nov. 13, 2002

(30) Foreign Application Priority Data
Nov. 21, 2001 (JP) 2001-355445

(51) Int. Cl. G01R 31/26

(52) U.S. Cl. 324/765

(57) ABSTRACT

To obtain a signal-off detection circuit with improved reliability of operation by permitting an issuing of an alarm to be set without being affected by any offset voltage of an amplifier. In the signal-off detection circuit of a data-receiving circuit including: a first amplifier for amplifying a received signal; a direct current feedback circuit for adding an offset voltage to an input of the amplifier; and a discrimination circuit for receiving the amplified output of the amplifier as input and performing discrimination of data, a second amplifier for amplifying the data is independently provided, and the amplified output of this amplifier is supplied to the signal-off detection circuit. Thereby, a threshold of the signal-off detection circuit is not affected by the offset voltage of the first amplifier, and therefore the signal-off detection circuit with improved reliability of operation can be obtained.

### BACKGROUND OF THE INVENTION

1. Field of the Invention

The present invention relates to a signal-off detection circuit and an optical receiving device using the detection circuit, and, in particular, to an improved signal-off detection circuit for detecting the disconnection of a data signal applied to the optical receiving device.

2. Description of the Related Art

When data signals to an optical receiving device are disconnected, that is, in the case of a break in the optical fiber or in the case of a failure of OFA (Optical Fiber Amplifier) in a WDM (Wave Length Division Multiplex) scheme, a function detecting a transmission line failure and issuing an alarm (LOS: Loss Of Signal) is required for isolating a failure to a transmission line failure and a device failure. Thus, this function is prescribed as an essential function by ITU (International Telecommunication Union).

When this alarm is issued, the system checks the operating state of its opposite device and performs operations such as switching the transmission line to a standby system (such an operation control is performed by a network management system of each device). After that, when all abnormal conditions have been resolved, the network management system checks communication to and from the opposite device and switches back from the standby system to the current use system. In this way, the alarm signal basically acts as a trigger for carrying out automatic switching between the system and the opposite device, and thus reliable operation for issuing alarms is required.

Conventional configuration for issuing this type of alarm is configured as shown in FIG. 4. Referring to FIG. 4, an optical signal from a transmission line, such as an optical fiber or the like, is converted into an electrical signal through O/E (light/electricity) conversion function not shown, and this converted input data signal is amplified in an amplifier 10 to an amplitude required by a discrimination circuit 12 of the following stage. The output of the amplifier 10 is divided into two part, and one is input to the discrimination circuit 12 and the other is input to a signal-off detection circuit 22.

For the amplifier 10, a limiter amplifier or an AGC (automatic gain control) amplifier are generally used. A direct current feedback circuit 11 is added between the input and output of the amplifier 10, and thus the input data signal is designed to be supplied to the discrimination circuit 12 of the following stage while a direct current voltage (offset voltage) is being given to the input data signal through the direct current feedback circuit 11. The following is the reason why the offset is given to the input data signal.

As described above, an optical receiving device comprises a stage for converting an optical input data signal from an optical signal into an electrical signal, or a stage for amplifying the data signal converted into the electrical signal to a predetermined amplitude. Here, AC-coupling through a capacitor or the like is used in each of the above amplifiers. Therefore, to ensure data discrimination in the discrimination circuit 12, the direct current feedback circuit 11 detects the direct current component of the data signal and adds an offset voltage corresponding to the direct current component to the input of the amplifier 10.

Particularly, in an optical communication system using an optical amplifier or an optical receiving circuit using APD (Avaranched Photo Diode) as a light receiving element, a difference occurs between the amounts of noise in the high level side and in the low level side of an optical received waveform (generally, the amount of noise in the high level side is larger). For this reason, in order to accurately discriminate between high levels and low levels when optical received power is small, it is required that a discrimination threshold of the discrimination circuit 12 should be shifted from the center value, and thus the amount of this shift becomes necessary as the offset voltage.

The configuration shown in FIG. 4 described above has an advantage that an amplifier required for obtaining an amplitude enough for the signal-off detection circuit 22 to determine the presence or absence of signals need not be independently provided, but can be shared with the amplifier 10 for the discrimination circuit 12.

However, as described above, in order that accurate data discrimination may be carried out in the discrimination circuit 12, the configuration of FIG. 4 requires that an offset voltage (direct current voltage) is given to the input data signal through the direct current feedback circuit 11 in the amplifier 10. In this case, however, variations in the offset voltage would cause variations in the input level to the signal-off detection circuit 22, thus resulting in unreliable alarm-issuing operation of the signal-off detection circuit 22 (see FIG. 5).

That is, if the offset voltage varies, as shown in an arrow in the drawing, with respect to a detection threshold (alarm-issuing threshold) for detecting the presence or absence of data signals in the signal-off detection circuit 22, the alarm-issuing operation thereof becomes unreliable.

Particularly, nowadays, the offset voltage has been actively controlled such that a data discrimination point in the discrimination circuit 12 may come to an optimum position according to the signal waveform (eye pattern) of input data signals. FIG. 6 shows an example of a configuration in such a case. In FIG. 6, the discrimination circuit 12 of FIG. 4 is replaced with a discrimination point automatic control function-having discrimination circuit 13. The discrimination point automatic control function-having discrimination circuit 13 has a function for automatically controlling a data discrimination point to the optimum value. Therefore, the offset voltage is always varying, and thus the configuration of FIG. 6 still has a disadvantage that alarm-issuing operation of the signal-off detection circuit 22 becomes more unreliable.

### SUMMARY OF THE INVENTION

An object of the present invention is to provide a signal-off detection circuit with improved reliability of operation by allowing the issuing of an alarm to be set without being affected by an offset voltage of the amplifier, and to provide an optical receiving circuit using the signal-off detection circuit.

The signal-off detection circuit according to the present invention is characterized by being independently provided with a signal-off amplifier for signal-off-detecting means for detecting the disconnection of an input data, in addition to a discrimination amplifier for discriminating means for performing discrimination of the above described input data. Further, the above described discrimination amplifier and the above described signal-off amplifier are characterized by each having offset-adding means for adding an offset voltage to their inputs.

Another signal-off detection circuit according to the present invention is a signal-off detection circuit provided in a data-receiving circuit comprising first amplifying means for amplifying an input data and discriminating means which receives an amplified output of the above described first amplifying means as input and performs discrimination of the above described data, and characterized by comprising a second amplifying means for amplifying the above described data and signal-off-detecting means for receiving the amplified output of the second amplifying means as input and detecting a loss of the data signal in the output.

The above described first and second amplifying means each are characterized by having offset-adding means for adding offset voltages to their input. Also, the above described signal-off-detecting means is characterized by being configured to generate a signal-off detection signal when the amplitude of the output of the above described second amplifying means is equal to or less than a given value. Further, each above described offset-adding means is characterized by having, as the above described offset voltage, a direct current voltage corresponding to the average value of the above described input data. Furthermore, the above described discriminating means is characterized by having a discrimination point automatic control function for controlling a threshold value for discrimination of data by the above described discriminating means to the optimum point therefor.

An optical receiving device according to the present invention is characterized by comprising the signal-off detection circuit of the above configuration and being integrated as an LSI circuit.

The operation according to the present invention will be described. In addition to an amplifier for amplifying input data and supplying it to a discriminating circuit that performs discrimination of the input data, an amplifier is independently provided for amplifying the input data and supplying it to a signal-off-detecting circuit that detects the disconnection state of the input data signal and issues an alarm. By such a configuration, it becomes possible to set a point for issuing an alarm without being affected at all by an offset voltage added to the discrimination circuit, thus achieving the reliable alarm-issuing operation. The present invention is particularly effective in a configuration in which an optimum point for discrimination is automatically controlled by actively controlling the offset voltage of the amplifier for the discrimination circuit.

### BRIEF DESCRIPTION OF THE DRAWINGS

FIG. 1 is a diagram for showing one embodiment of the present invention;

FIG. 2A and FIG. 2B are waveform diagrams for showing examples of operation of a circuit in FIG. 1;

FIG. 3 is a diagram for showing another embodiment of the present invention;

FIG. 4 is a circuit diagram for showing a conventional example;

FIG. 5 is a diagram for showing a relation between an alarm-issuing threshold and an offset voltage in a circuit in FIG. 4; and

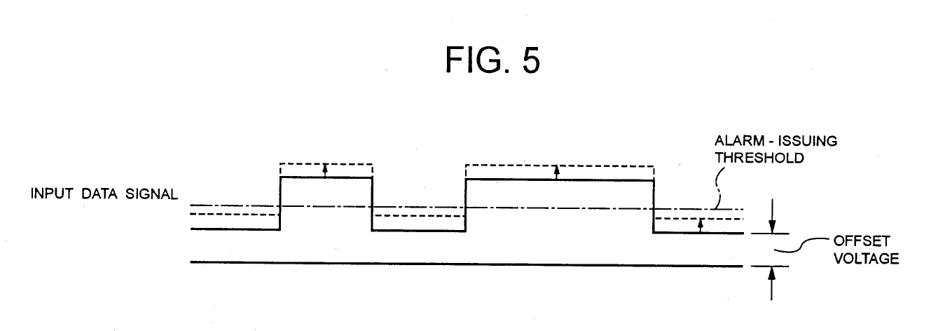

FIG. 6 is a circuit diagram for showing another conventional example.

### DETAILED DESCRIPTION OF THE PREFERRED EMBODIMENTS

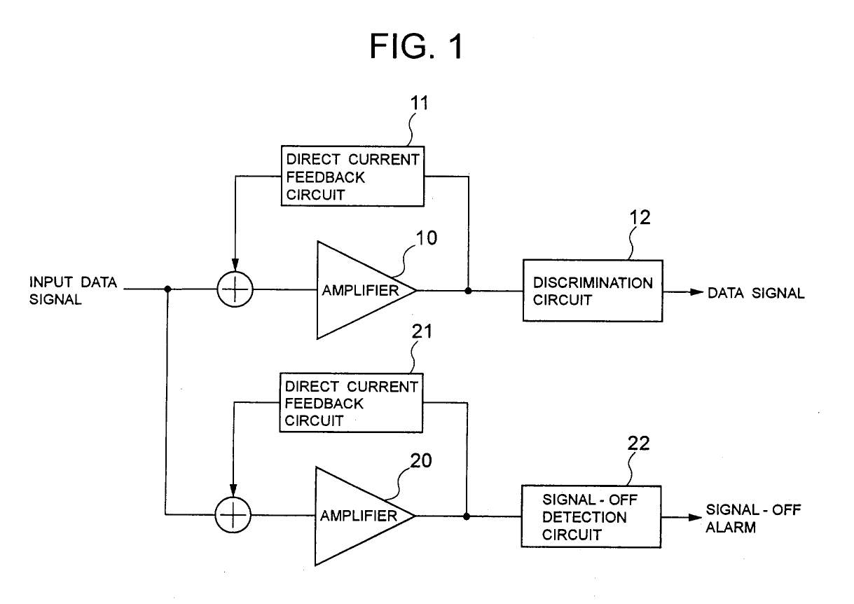

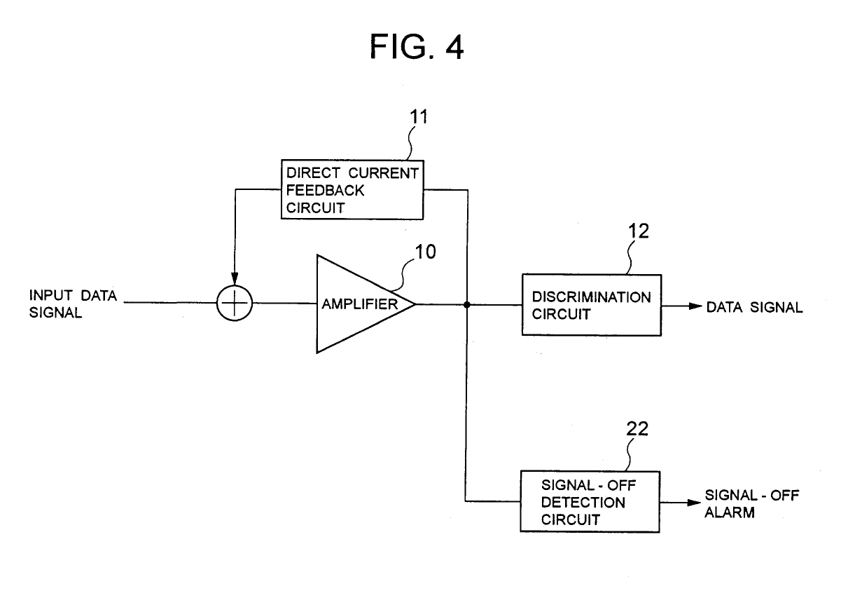

Hereinafter, embodiments of the present invention will be described referring to drawings. FIG. 1 is a diagram for showing a configuration of a first embodiment of the present invention. In FIG. 1, the parts similar to those of FIG. 4 are indicated with the same symbols. Referring to FIG. 1, an amplifier 10 is for amplifying an input data signal, converted from an optical signal to an electrical signal, to an amplitude required for discriminating the data signal in a discrimination circuit 12. For the amplifier 10, a limiter amplifier and an AGC amplifier are generally used, which is the same as in the conventional example shown in FIG. 4.

A direct current feedback circuit 11 is for detecting an average value of the signal component to give an offset voltage to the input data signal to the discrimination circuit 12, and the discrimination circuit 12 discriminates between “1” and “0” of the input data signals. Generally, D-FF (D-type flip flop) is used for the discrimination circuit 12. An amplifier 20 is for amplifying the input data signal, converted from the optical signal to the electrical signal, to an amplitude required by a signal-off detection circuit 22, and the amplifier 20 is a separate amplifier provided independently of the amplifier 10 for the discrimination circuit 12, and a general amplifier is used for the amplifier 20.

A direct current feedback circuit 21 detects an average value of the signal component to give an offset voltage to the input data signal for the signal-off detection circuit 22. The reason why the offset voltage is given to the input data signal is the same as in the case of the amplifier 10 for the discrimination circuit 12. The signal-off detection circuit 22 detects the presence or absence of input data signals and issues alarms when the amplitudes of the input signals become equal to or less than a given value.

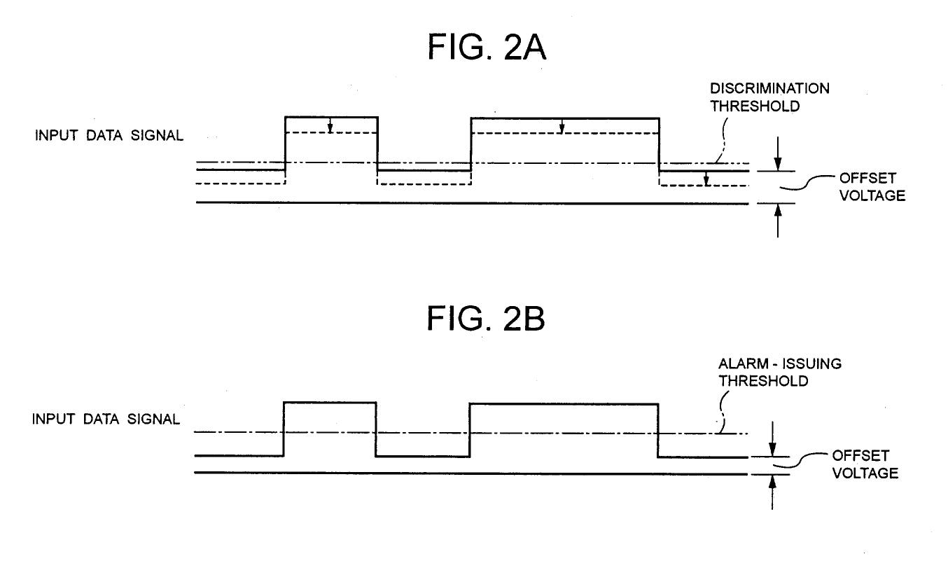

FIG. 2A and FIG. 2B are examples of waveform diagrams for showing the operation of the circuit of FIG. 1. The operation of the circuit of FIG. 1 will be described with reference to FIG. 2A and FIG. 2B. Even if variations occur in the offset voltage of input data signals for the discrimination circuit 12 as shown in FIG. 2A, the offset voltage for the signal-off detection circuit 22 is clearly unaffected by the variations, and therefore the circuit 22 can detect the presence or absence of input data signals with stability as shown in FIG. 2B.

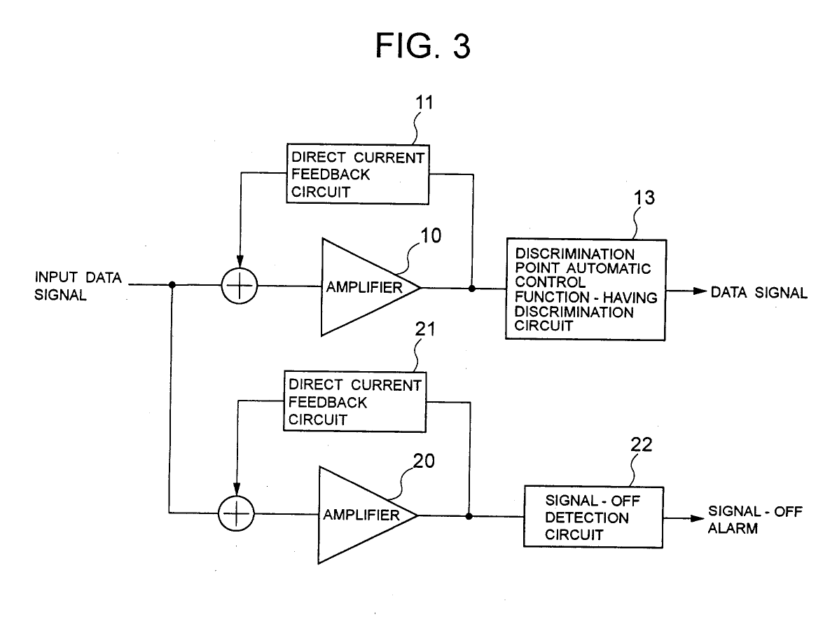

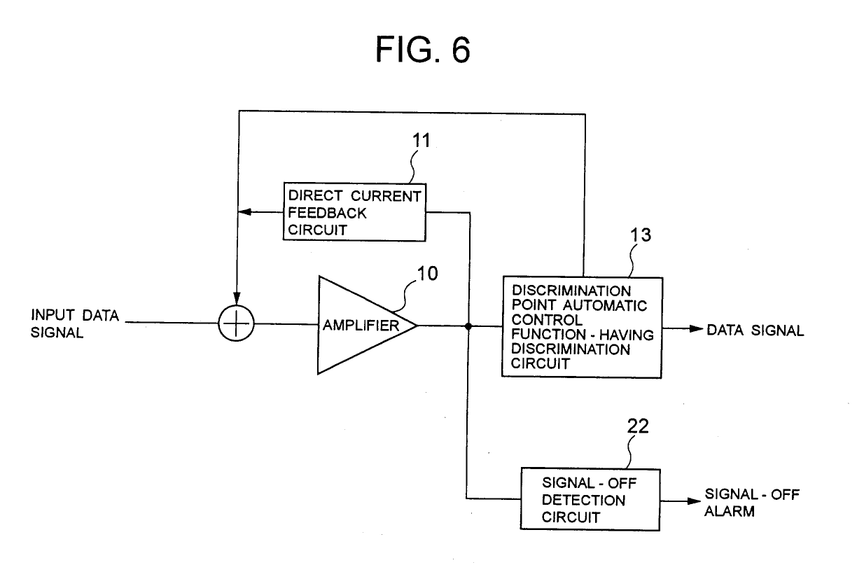

FIG. 3 is a diagram for showing another embodiment of the present invention, and in this drawing, the parts similar to those of FIG. 1 and FIG. 6 are shown by the same symbols. The present embodiment has a configuration in which a discrimination point automatic control function-having discrimination circuit 13 is used in place of the discrimination circuit 12 of FIG. 1. The other configurations are similar to those of FIG. 1.

The discrimination point automatic control function-having discrimination circuit 13 is designed such that it may actively control the offset voltages of input data signals for the discrimination circuit 12 to provide an optimum discrimination point therefor at all times, and thus the offset voltage of input data signals is always varying (see FIG. 2A). Even in such a case, the variation does not affect the offset voltage for the signal-off detection circuit 22, which can detect the presence or absence of input data signals with stability (see FIG. 2B).

By the way, since the configuration of the discrimination point automatic control function-having discrimination circuit 13 is well known from Japanese Patent Laid-Open Nos. 9-270755 and 10-13396 or the like, it is not particularly explained here. Also, various known circuit configurations can be used for the signal-off detection circuit 22, of which circuit configuration is particularly not limited naturally. Also, the device according to the present invention is applicable to an optical receiving device of a WDM communication scheme or the like, and further, generally, it is widely applicable to receiving devices of any scheme in which an amplifier is used to discriminate received data and an offset voltage for discrimination of the data is given to the input of the amplifier.

Further, the circuit configurations according to the present invention as shown in FIG. 1 or FIG. 3 constitute part of an optical receiving device, which device is generally integrated as an LSI circuit and configured into a module. In this case, even if an additional amplifier 20 for the signal-off detection circuit 22 is added to the LSI circuit, it is apparent that this fact causes almost no problem concerned with reduction of the scale of integration of the LSI circuit.

As described hereinbefore, according to the present invention, because a separate amplifier circuit for a signal-off detection circuit is provided in addition to an amplifier for a discrimination circuit, it is possible to set a point for issuing an alarm without being affected by the offset voltage of the amplifier for a discrimination circuit, thus resulting in an advantage of reliable operation. Particularly, the present invention is effective in case of actively controlling the offset voltage of the amplifier for a discrimination circuit to automatically control an optimum point for discrimination.

What is claimed is:

1. A signal-off detection circuit, independently comprising a signal-off amplifier for signal-off-detecting means for detecting disconnection of an input data, in addition to a discrimination amplifier for discriminating means for performing discrimination of said input data.

2. The signal-off detection circuit according to claim 1, wherein said discrimination amplifier and said signal-off amplifier each have offset-adding means for adding an offset voltage to input.

3. A signal-off detection circuit used in a data-receiving circuit including first amplifying means for amplifying an input data and discriminating means which receives an amplified output of said first amplifying means as input and performs discrimination of said data, comprising:
second amplifying means for amplifying said data; and
signal-off-detecting means for receiving the amplified output of said second amplifying means as input and detecting disconnection of the data signal therein.

4. The signal-off detection circuit according to claim 3, wherein said first and second amplifying means each have offset-adding means for adding offset voltages to their inputs.

5. The signal-off detection circuit according to claim 3, wherein said signal-off-detecting means is configured to generate a signal-off detection signal when the amplitude of the output of said second amplifying means is equal to or less than a definite value.

6. The signal-off detection circuit according to claim 2, wherein each said offset-adding means has, as said offset voltage, a direct current voltage corresponding to the average value of said input data.

7. The signal-off detection circuit according to claim 1, wherein said discriminating means has a discrimination point automatic control function for controlling a threshold value for discrimination of data in said discriminating means to an optimum point thereof.

8. An optical receiving device, having a signal-off detection circuit according to claim 1.

9. The optical receiving device according to claim 8, wherein said optical receiving device is integrated as an LSI circuit.

10. The optical receiving device according to claim 8, wherein said optical receiving device is of a WDM communication scheme.
